(19) United States
(12) Patent Application Publication
(10) Pub. No.: US 2015/0001741 A1
(43) Pub. Date: Jan. 1, 2015

(54) Semiconductor Device and Method of Forming an Interposer Including a Beveled Edge

(71) Applicant: STATS ChipPAC, Ltd., Singapore (SG)

(72) Inventors: Koo Hong Lee, Seoul (KR); Tae Keun Lee, Gyeonggi-do (KR)

(21) Appl. No.: 13/929,426

(22) Filed: Jun. 27, 2013

(51) Int. Cl. H01L 23/31; H01L 21/56

(52) U.S. Cl. CPC H01L 23/3114; H01L 21/565
USPC 257/787; 438/107

(57) ABSTRACT

A semiconductor device includes a first substrate. The first substrate may be a wafer-level interposer or a die-level interposer. A portion of the first substrate is removed to form a beveled edge. The beveled edge may be formed during singulation of the first substrate. A second substrate is disposed over the first substrate. The beveled edge is oriented towards the second substrate. A semiconductor die is disposed over the second substrate. The first and second substrates are disposed within a cavity of a mold. An encapsulant is deposited within the cavity over a first surface of the first substrate between the first and second substrates. The beveled edge reduces encapsulant flow onto a second surface of the first substrate opposite the first surface. The second surface of the first substrate remains free from the encapsulant. The first substrate is singulated before or after the encapsulant is deposited.

### FIELD OF THE INVENTION

The present invention relates in general to semiconductor devices and, more particularly, to a semiconductor device and method of forming an interposer having a beveled edge for better mold flow.

### BACKGROUND OF THE INVENTION

Semiconductor devices are commonly found in modern electronic products. Semiconductor devices vary in the number and density of electrical components. Discrete semiconductor devices generally contain one type of electrical component, e.g., light emitting diode (LED), small signal transistor, resistor, capacitor, inductor, and power metal oxide semiconductor field effect transistor (MOSFET). Integrated semiconductor devices typically contain hundreds to millions of electrical components. Examples of integrated semiconductor devices include microcontrollers, microprocessors, charged-coupled devices (CCDs), solar cells, and digital micro-mirror devices (DMDs).

Semiconductor devices perform a wide range of functions such as signal processing, high-speed calculations, transmitting and receiving electromagnetic signals, controlling electronic devices, transforming sunlight to electricity, and creating visual projections for television displays. Semiconductor devices are found in the fields of entertainment, communications, power conversion, networks, computers, and consumer products. Semiconductor devices are also found in military applications, aviation, automotive, industrial controllers, and office equipment.

Semiconductor devices exploit the electrical properties of semiconductor materials. The atomic structure of semiconductor material allows its electrical conductivity to be manipulated by the application of an electric field or base current or through the process of doping. Doping introduces impurities into the semiconductor material to manipulate and control the conductivity of the semiconductor device.

A semiconductor device contains active and passive electrical structures. Active structures, including bipolar and field effect transistors, control the flow of electrical current. By varying levels of doping and application of an electric field or base current, the transistor either promotes or restricts the flow of electrical current. Passive structures, including resistors, capacitors, and inductors, create a relationship between voltage and current necessary to perform a variety of electrical functions. The passive and active structures are electrically connected to form circuits, which enable the semiconductor device to perform high-speed calculations and other useful functions.

Semiconductor devices are generally manufactured using two complex manufacturing processes, i.e., front-end manufacturing, and back-end manufacturing, each involving potentially hundreds of steps. Front-end manufacturing involves the formation of a plurality of die on the surface of a semiconductor wafer. Each semiconductor die is typically identical and contains circuits formed by electrically connecting active and passive components. Back-end manufacturing involves singulating individual semiconductor die from the finished wafer and packaging the die to provide structural support and environmental isolation. The term “semiconductor die” as used herein refers to both the singular and plural form of the words, and accordingly can refer to both a single semiconductor device and multiple semiconductor devices.

One goal of semiconductor manufacturing is to produce smaller semiconductor devices. Smaller devices typically consume less power, have higher performance, and can be produced more efficiently. In addition, smaller semiconductor devices have a smaller footprint, which is desirable for smaller end products. A smaller semiconductor die size can be achieved by improvements in the front-end process resulting in semiconductor die with smaller, higher density active and passive components. Back-end processes may result in semiconductor device packages with a smaller footprint by improvements in electrical interconnection and packaging materials.

FIG. 1a shows a semiconductor die 10 mounted over a substrate 12 with bumps 14. An underfill material 16 is formed between semiconductor die 10 and substrate 12. Conventional interposer 18 is mounted over semiconductor die 10 and substrate 12 with bumps 20 to form a semiconductor package. The semiconductor package placed into a molding apparatus 22. An encapsulant 24 is deposited around semiconductor die 10 to fill a gap between conventional interposer 18 and substrate 12. During the encapsulation process, encapsulant 24 leaks or flows onto top surface 26 of conventional interposer 18. FIG. 1b shows a semiconductor package with encapsulant 24 overflow on top surface 26 of conventional interposer 18. Bumps 28 are formed on the surface of substrate 12 opposite semiconductor die 10. The process of molding a semiconductor package results in the encapsulant material leaking or flowing onto electrical contacts on a top surface of the semiconductor package. The encapsulant leaves residue and other contaminants on the surface of the interposer, which can interfere with electrical connections and reduce electrical performance of the semiconductor package. Encapsulant covering the contact pads on the top surface of the semiconductor package causes problems when mounting additional semiconductor devices to the interposer surface.

### SUMMARY OF THE INVENTION

A need exists for a semiconductor package including an interposer with better performance during molding. Accordingly, in one embodiment, the present invention is a method of making a semiconductor device comprising the steps of providing a first substrate, removing a portion of the first substrate to form a beveled edge, and depositing an encapsulant over a first surface of the first substrate. The beveled edge reduces encapsulant flow onto a second surface of the first substrate opposite the first surface.

In another embodiment, the present invention is a method of making a semiconductor device comprising the steps of providing a first substrate, removing a portion of the first substrate to form a beveled edge, and depositing an encapsulant over the first substrate.

In another embodiment, the present invention is a semiconductor device comprising a first substrate including a beveled edge and an encapsulant deposited over the first substrate and over the beveled edge.

In another embodiment, the present invention is a semiconductor device comprising a first substrate including a beveled edge and an encapsulant deposited over the first substrate.

### BRIEF DESCRIPTION OF THE DRAWINGS

FIGS. 1a-1b illustrate a process of molding a semiconductor package including a conventional interposer;

FIG. 2 illustrates a printed circuit board (PCB) with different types of packages mounted to a surface of the PCB;

FIGS. 3a-3c illustrate further detail of the representative semiconductor packages mounted to the PCB;

FIGS. 4a-4c illustrate a semiconductor wafer with a plurality of semiconductor die separated by a saw street;

FIGS. 5a-5b illustrate a process of forming an interposer with a beveled edge;

FIG. 6 illustrates an interposer with a beveled edge;

FIGS. 7a-7c illustrates a process of molding a semiconductor package including an interposer with a beveled edge; and

FIGS. 8a-8b illustrates a semiconductor package formed by a process of molding a semiconductor package including an interposer with a beveled edge.

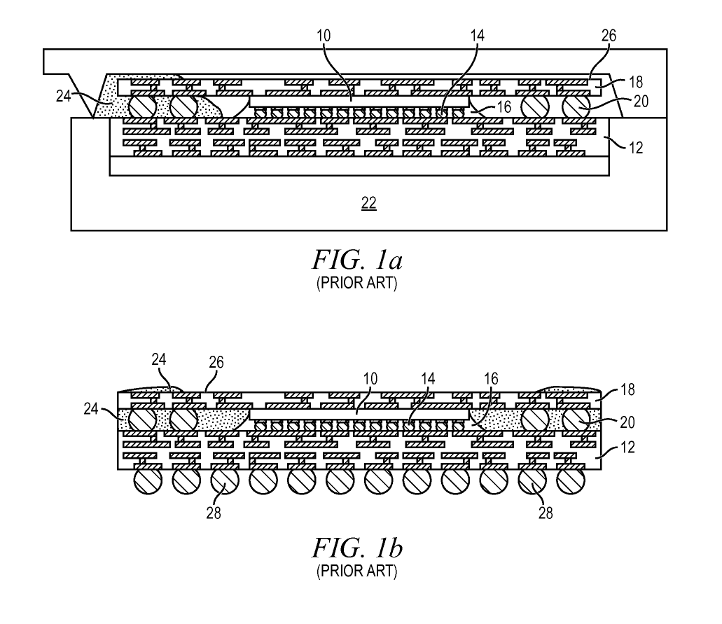

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Passive and active components are formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices by dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition can involve chemical vapor deposition (CVD), physical vapor deposition (PVD), electrolytic plating, and electroless plating processes. Each layer is generally patterned to form portions of active components, passive components, or electrical connections between components.

Back-end manufacturing refers to cutting or singulating the finished wafer into the individual semiconductor die and then packaging the semiconductor die for structural support and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are mounted to a package substrate that includes pins or contact pads for interconnection with other system components. Contact pads formed over the semiconductor die are then connected to contact pads within the package. The electrical connections can be made with solder bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

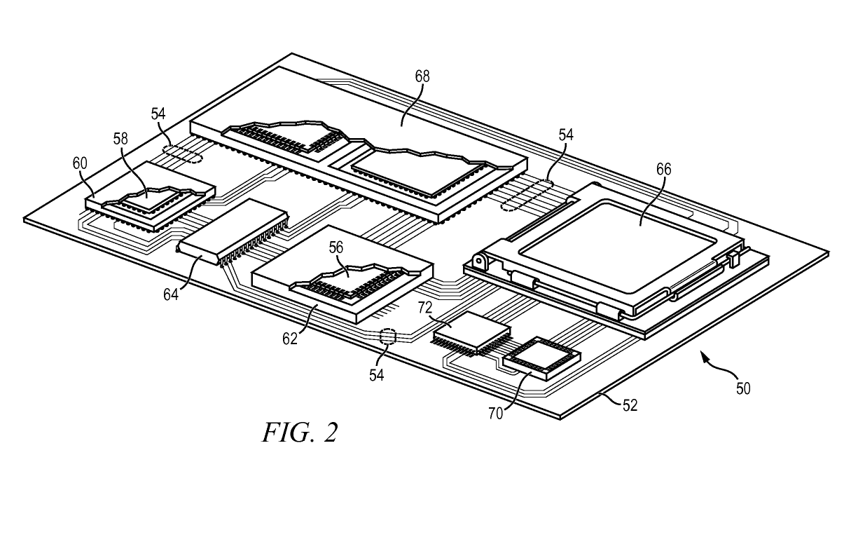

FIG. 2 illustrates electronic device 50 having a chip carrier substrate or printed circuit board (PCB) 52 with a plurality of semiconductor packages mounted on its surface. Electronic device 50 can have one type of semiconductor package, or multiple types of semiconductor packages, depending on the application. The different types of semiconductor packages are shown in FIG. 2 for purposes of illustration.

Electronic device 50 can be a stand-alone system that uses the semiconductor packages to perform one or more electrical functions. Alternatively, electronic device 50 can be a subcomponent of a larger system. For example, electronic device 50 can be part of a cellular phone, personal digital assistant (PDA), digital video camera (DVC), or other electronic communication device. Alternatively, electronic device 50 can be a graphics card, network interface card, or other signal processing card that can be inserted into a computer. The semiconductor package can include microprocessors, memories, application specific integrated circuits (ASIC), logic circuits, analog circuits, RF circuits, discrete devices, or other semiconductor die or electrical components. Miniaturization and weight reduction are essential for the products to be accepted by the market. The distance between semiconductor devices must be decreased to achieve higher density.

In FIG. 2, PCB 52 provides a general substrate for structural support and electrical interconnect of the semiconductor packages mounted on the PCB. Conductive signal traces 54 are formed over a surface or within layers of PCB 52 using evaporation, electrolytic plating, electroless plating, screen printing, or other suitable metal deposition process. Signal traces 54 provide for electrical communication between each of the semiconductor packages, mounted components, and other external system components. Traces 54 also provide power and ground connections to each of the semiconductor packages.

In some embodiments, a semiconductor device has two packaging levels. First level packaging is a technique for mechanically and electrically attaching the semiconductor die to an intermediate carrier. Second level packaging involves mechanically and electrically attaching the intermediate carrier to the PCB. In other embodiments, a semiconductor device may only have the first level packaging where the die is mechanically and electrically mounted directly to the PCB.

For the purpose of illustration, several types of first level packaging, including bond wire package 56 and flipchip 58, are shown on PCB 52. Additionally, several types of second level packaging, including ball grid array (BGA) 60, bump chip carrier (BCC) 62, dual in-line package (DIP) 64, land grid array (LGA) 66, multi-chip module (MCM) 68, quad flat non-leaded package (QFN) 70, and quad flat package 72, are shown mounted on PCB 52. Depending upon the system requirements, any combination of semiconductor packages, configured with any combination of first and second level packaging styles, as well as other electronic components, can be connected to PCB 52. In some embodiments, electronic device 50 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and less expensive to manufacture resulting in a lower cost for consumers.

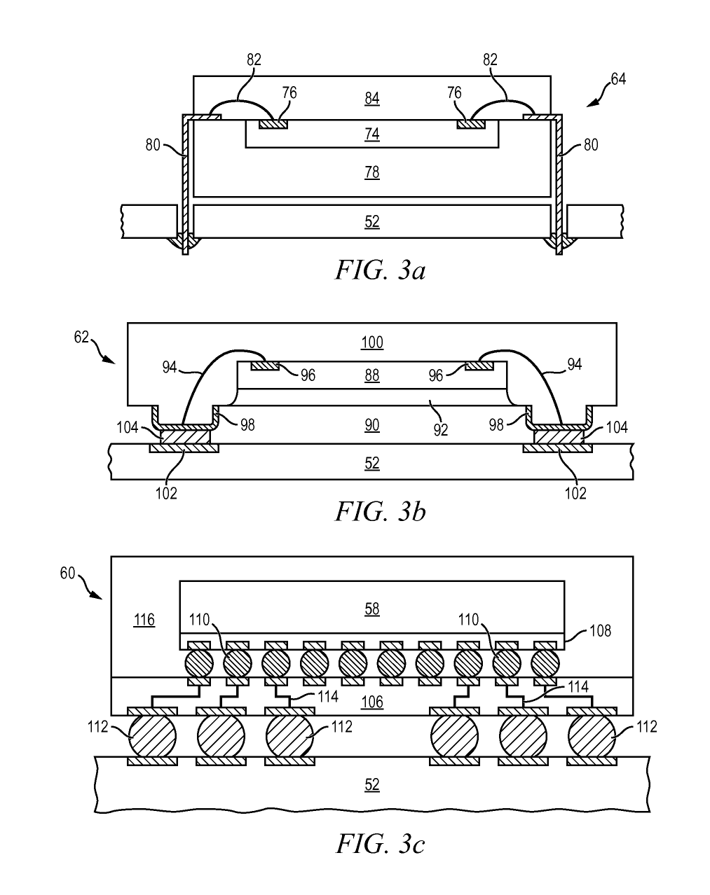

FIGS. 3a-3c show exemplary semiconductor packages. FIG. 3a illustrates further detail of DIP 64 mounted on PCB 52. Semiconductor die 74 includes an active region containing analog or digital circuits implemented as active devices, passive devices, conductive layers, and dielectric layers formed within the die and are electrically interconnected according to the electrical design of the die. For example, the circuit can include one or more transistors, diodes, inductors, capacitors, resistors, and other circuit elements formed within the active region of semiconductor die 74. Contact pads 76 are one or more layers of conductive material, such as aluminum (Al), copper (Cu), tin (Sn), nickel (Ni), gold (Au), or silver (Ag), and are electrically connected to the circuit elements formed within semiconductor die 74. During assembly of DIP 64, semiconductor die 74 is mounted to an intermediate carrier 78 using a gold-silicon eutectic layer or adhesive material such as thermal epoxy or epoxy resin. The package body includes an insulative packaging material such as polymer or ceramic. Conductor leads 80 and bond wires 82 provide electrical interconnect between semiconductor die 74 and PCB 52. Encapsulant 84 is deposited over the package for environmental protection by preventing moisture and particles from entering the package and contaminating semiconductor die 74 or bond wires 82.

FIG. 3b illustrates further detail of BCC 62 mounted on PCB 52. Semiconductor die 88 is mounted over carrier 90 using an underfill or epoxy-resin adhesive material 92. Bond wires 94 provide first level packaging interconnect between contact pads 96 and 98. Molding compound or encapsulant 100 is deposited over semiconductor die 88 and bond wires 94 to provide physical support and electrical isolation for the device. Contact pads 102 are formed over a surface of PCB 52 using a suitable metal deposition process such as electrolytic plating or electroless plating to prevent oxidation. Contact pads 102 are electrically connected to one or more conductive signal traces 54 in PCB 52. Bumps 104 are formed between contact pads 98 of BCC 62 and contact pads 102 of PCB 52.

In FIG. 3c, semiconductor die 58 is mounted face down to intermediate carrier 106 with a flipchip style first level packaging. Active region 108 of semiconductor die 58 contains analog or digital circuits implemented as active devices, passive devices, conductive layers, and dielectric layers formed according to the electrical design of the die. For example, the circuit can include one or more transistors, diodes, inductors, capacitors, resistors, and other circuit elements within active region 108. Semiconductor die 58 is electrically and mechanically connected to carrier 106 through bumps 110.

BGA 60 is electrically and mechanically connected to PCB 52 with a BGA style second level packaging using bumps 112. Semiconductor die 58 is electrically connected to conductive signal traces 54 in PCB 52 through bumps 110, signal lines 114, and bumps 112. A molding compound or encapsulant 116 is deposited over semiconductor die 58 and carrier 106 to provide physical support and electrical isolation for the device. The flipchip semiconductor device provides a short electrical conduction path from the active devices on semiconductor die 58 to conduction tracks on PCB 52 in order to reduce signal propagation distance, lower capacitance, and improve overall circuit performance. In another embodiment, the semiconductor die 58 can be mechanically and electrically connected directly to PCB 52 using flipchip style first level packaging without intermediate carrier 106.

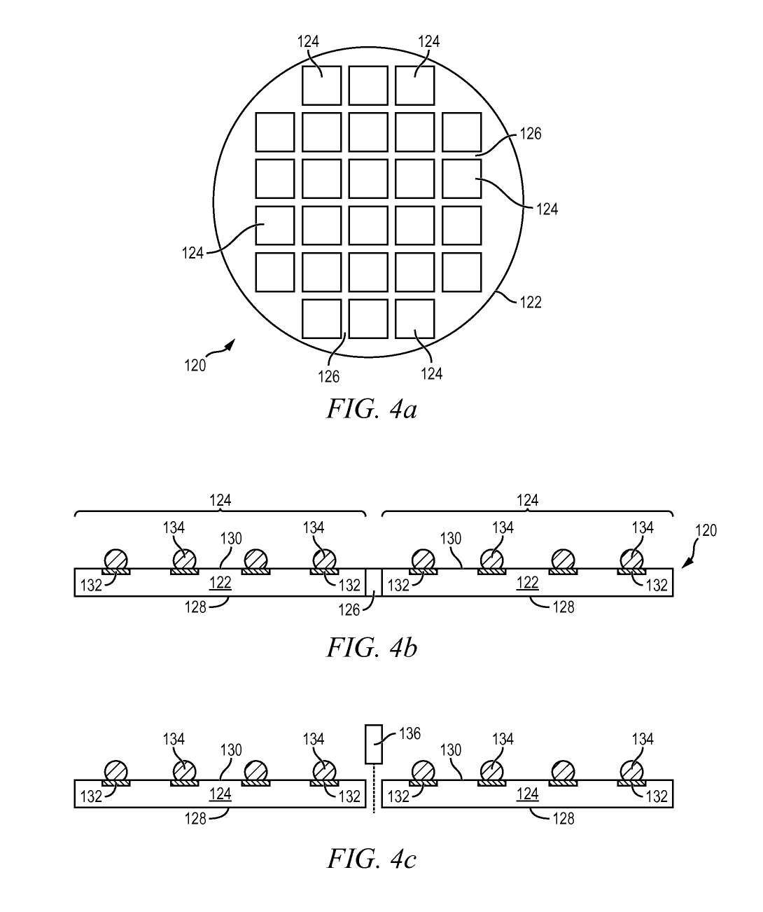

FIG. 4a shows a semiconductor wafer 120 with a base substrate material 122, such as silicon, germanium, gallium arsenide, indium phosphide, or silicon carbide, for structural support. A plurality of semiconductor die or components 124 is formed on wafer 120 separated by a non-active, inter-die wafer area or saw street 126 as described above. Saw street 126 provides cutting areas to singulate semiconductor wafer 120 into individual semiconductor die 124.

FIG. 4b shows a cross-sectional view of a portion of semiconductor wafer 120. Each semiconductor die 124 has a back surface 128 and active surface 130 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 130 to implement analog circuits or digital circuits, such as digital signal processor (DSP), ASIC, memory, or other signal processing circuit. Semiconductor die 124 may also contain integrated passive devices (IPDs), such as inductors, capacitors, and resistors, for RF signal processing. In one embodiment, semiconductor die 124 is a flipchip type device.

An electrically conductive layer 132 is formed over active surface 130 using PVD, CVD, electrolytic plating, electroless plating process, or other suitable metal deposition process. Conductive layer 132 can be one or more layers of Al, Cu, Sn, Ni, Au, Ag, or other suitable electrically conductive material. Conductive layer 132 operates as contact pads electrically connected to the circuits on active surface 130. Conductive layer 132 can be formed as contact pads disposed side-by-side a first distance from the edge of semiconductor die 124, as shown in FIG. 4b. Alternatively, conductive layer 132 can be formed as contact pads that are offset in multiple rows such that a first row of contact pads is disposed a first distance from the edge of the die, and a second row of contact pads alternating with the first row is disposed a second distance from the edge of the die.

An electrically conductive bump material is deposited over contact pads 132 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to contact pads 132 using a suitable attachment or bonding process. In one embodiment, the bump material is reflowed by heating the material above its melting point to form balls or bumps 134. In some applications, bumps 134 are reflowed a second time to improve electrical contact to contact pads 132. Bumps 134 can also be compression bonded or thermocompression bonded to contact pads 132. Bumps 134 represent one type of interconnect structure that can be formed over contact pads 132. The interconnect structure can also use stud bump, micro bump, or other electrical interconnect.

In FIG. 4c, semiconductor wafer 120 is singulated through saw street 126 using a saw blade or laser cutting tool 136 into individual semiconductor die 124.

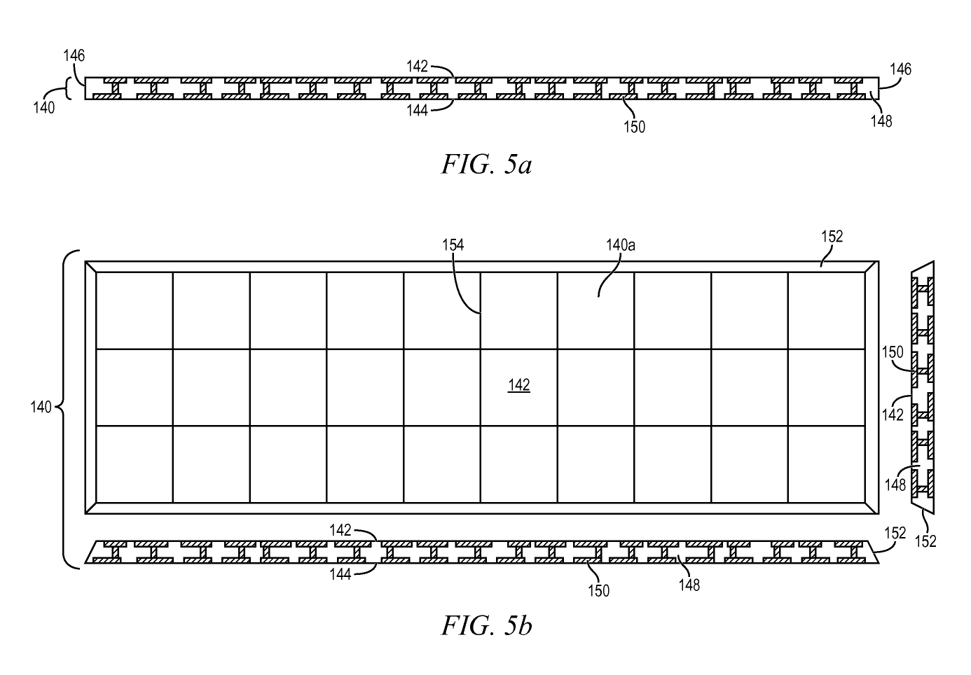

FIGS. 5a-5b illustrate, in relation to FIGS. 2 and 3a-3c, a process of forming an interposer with beveled edges for better mold flow during an encapsulation process. FIG. 5a shows a substrate or interposer 140 including surface 142, surface 144 opposite surface 142, and edges 146. Interposer 140 can be a laminate interposer, PCB, wafer-form, or strip interposer. Interposer 140 includes one or more insulating or passivation layers 148 and one or more conductive layers 150. Interposer 140 may include one or more laminated layers of polytetrafluoroethylene pre-impregnated (prepreg), FR-4, FR-1, CEM-1, or CEM-3 with a combination of phenolic cotton paper, epoxy, resin, woven glass, matte glass, polyester, and other reinforcement fibers or fabrics. Insulating layers 148 may contain one or more layers of silicon dioxide (SiO2), silicon nitride (Si3N4), silicon oxynitride (SiON), tantalum pentoxide (Ta2O5), aluminum oxide (Al2O3), or other material having similar insulating and structural properties. Interposer 140 can also be a multi-layer flexible laminate, ceramic, copper foil, glass, or semiconductor wafer including an active surface containing one or more transistors, diodes, and other circuit elements to implement analog circuits or digital circuits.

Interposer 140 includes an electrically conductive layer or redistribution layer (RDL) 150 formed using sputtering, electrolytic plating, electroless plating, or other suitable deposition process. Conductive layer 150 can be one or more layers of Al, Cu, Sn, Ni, Au, Ag, titanium (Ti), tungsten (W), or other suitable electrically conductive material. Conductive layers 150 provide vertical and horizontal conduction paths through interposer 140. Portions of conductive layers 150 are electrically common or electrically isolated according to the design and function of the semiconductor die to be mounted to interposer 140.

In FIG. 5b, a portion of insulating layer 148 is removed from interposer 140 at edges 146 using a saw blade or laser cutting tool resulting in chamfered or beveled edges 152. A beveled, angled, or “V”-shaped saw blade can be used to create beveled edges 152. The cutting tool cuts an angled or sloped side surface into insulating layer 148 of interposer 140 to form beveled edges 152. Before forming beveled edges 152, interposer 140 includes edges 146, which form approximately a 90 degree angle with surfaces 142 and 144 of interposer 140. After forming beveled edges 152, beveled edges 152 may form a 45 degree angle with respect to surface 142 or 144. The angle of beveled edges 152 can be any angle greater than or less than 90 degrees. In one embodiment, interposer 140 is narrower at surface 142 than at surface 144, and a cross section of interposer 140 is trapezoid-shaped. Interposer 140 further includes a plurality of interposer units 140a separated by saw streets 154.

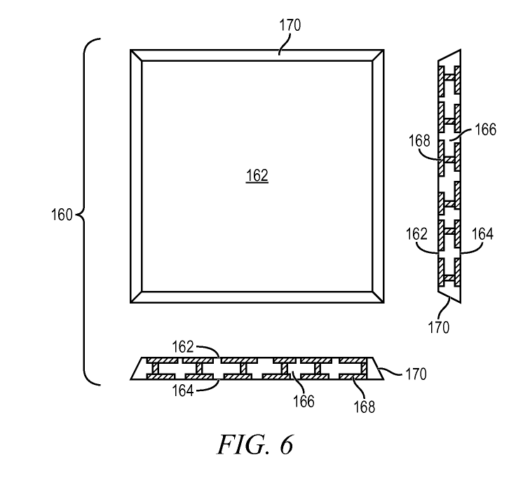

FIG. 6 illustrate another interposer with beveled edges for better mold flow during encapsulation. FIG. 6 shows a substrate or interposer 160 including surface 162 and surface 164 opposite surface 162. Interposer 160 can be a laminate interposer, PCB, or die-form interposer. Interposer 160 includes one or more insulating or passivation layers 166 and one or more conductive layers 168. Interposer 160 may include one or more laminated layers of prepreg, FR-4, FR-1, CEM-1, or CEM-3 with a combination of phenolic cotton paper, epoxy, resin, woven glass, matte glass, polyester, and other reinforcement fibers or fabrics. Insulating layers 166 may contain one or more layers of SiO2, Si3N4, SiON, Ta2O5, Al2O3, or other material having similar insulating and structural properties. Interposer 160 can also be a multi-layer flexible laminate, ceramic, copper foil, glass, or semiconductor wafer including an active surface containing one or more transistors, diodes, and other circuit elements to implement analog circuits or digital circuits.

Interposer 160 includes an electrically conductive layer or RDL 168 formed using sputtering, electrolytic plating, electroless plating, or other suitable deposition process. Conductive layer 168 can be one or more layers of Al, Cu, Sn, Ni, Au, Ag, Ti, W, or other suitable electrically conductive material. Conductive layers 168 provide vertical and horizontal conduction paths through interposer 160. Portions of conductive layers 168 are electrically common or electrically isolated according to the design and function of the semiconductor die to be mounted to interposer 160.

Interposer 160 can be formed by singulating a strip interposer, such as interposer 140 from FIG. 5a, into singulated interposers 160 using a saw blade or laser cutting tool. A beveled, angled, or “V”-shaped saw blade can be used for singulation to form interposer 160 with chamfered or beveled edges 170. The cutting tool cuts an angled or sloped side surface into insulating layer 166 of interposer 160. A cross section of interposer 160 including beveled edges 170 is trapezoid-shaped. In one embodiment, interposer 160 is narrower at surface 162 than at surface 164. Beveled edges 170 may form a 45 degree with respect to surface 162 or 164. The angle of beveled edge 170 can be any angle greater than or less than 90 degrees.

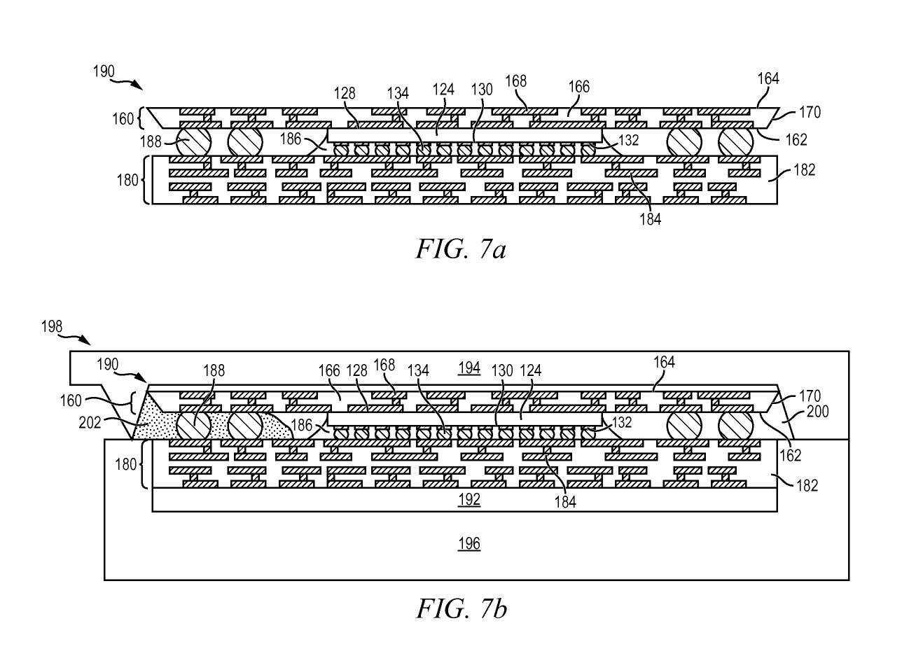

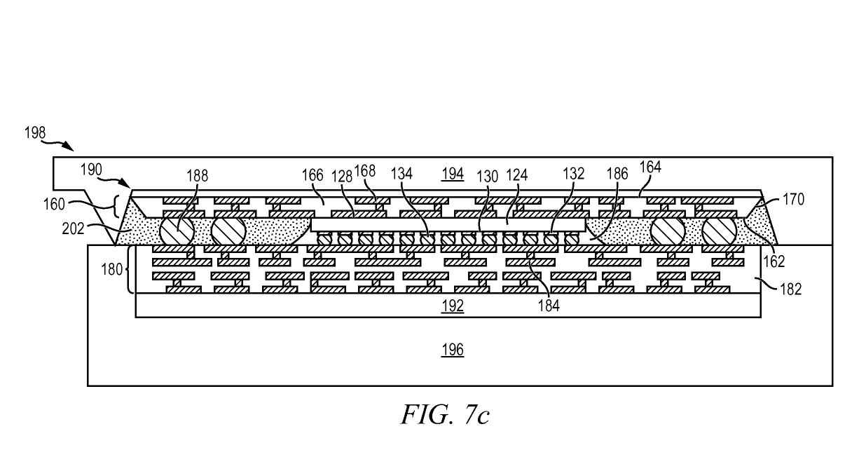

FIGS. 7a-7c show a process of molding a semiconductor package having a top interposer for better mold flow. In FIG. 7a, semiconductor die 124 from FIGS. 4a-4c are positioned over and mounted to substrate or interposer 180 with bumps 134. Substrate 180 can be a die-level or wafer-level interposer. Substrate 180 includes one or more insulating or passivation layers 182 and one or more conductive layers 184. Substrate 180 may include one or more laminated layers of prepreg, FR-4, FR-1, CEM-1, or CEM-3 with a combination of phenolic cotton paper, epoxy, resin, woven glass, matte glass, polyester, and other reinforcement fibers or fabrics. Insulating layers 182 may contain one or more layers of SiO2, Si3N4, SiON, Ta2O5, Al2O3, or other material having similar insulating and structural properties. Substrate 180 can also be a multi-layer flexible laminate, ceramic, copper foil, glass, or semiconductor wafer including an active surface containing one or more transistors, diodes, and other circuit elements to implement analog circuits or digital circuits.

Substrate 180 includes an electrically conductive layer or RDL 184 formed using a patterning and metal deposition process such as sputtering, electrolytic plating, and electroless plating. Conductive layer 184 can be one or more layers of Al, Cu, Sn, Ni, Au, Ag, Ti, W, or other suitable electrically conductive material. Conductive layers 184 provide vertical and horizontal conduction paths through substrate 180. Portions of conductive layers 184 are electrically common or electrically isolated according to the design and function of the semiconductor die 124 mounted to substrate 180. Semiconductor die 124 is mounted with active surface 130 oriented downwards toward substrate 180. The circuits on active surface 130 of semiconductor die 124 are electrically connected through conductive layer 132 and bumps 134 to conductive layers 184 of substrate 180.

An underfill material 186 is deposited between semiconductor die 124 and substrate 180 using a paste printing, compressive molding, transfer molding, liquid encapsulant molding, vacuum lamination, spin coating, mold underfill, or other suitable application process. Underfill material 186 can be polymer composite material, such as epoxy resin with filler, epoxy acrylate with filler, or polymer with proper filler. Underfill material 186 is non-conductive and environmentally protects the semiconductor device from external elements and contaminants. In particular, underfill material 186 is disposed along the sides of semiconductor die 124 and in the gap between active surface 130 and substrate 180. Alternatively, semiconductor die 124 is mounted over substrate 180 using an underfill or epoxy-resin adhesive material.

Interposer 160 is mounted over semiconductor die 124 and substrate 180 with bumps 188 to form semiconductor package 190. An electrically conductive bump material is deposited over conductive layer 168 using an evaporation, electrolytic plating, electroless plating, ball drop, or screen printing process. In one embodiment, the bump material is deposited with a ball drop stencil, i.e., no mask required. The bump material can be Al, Sn, Ni, Au, Ag, lead (Pb), Bi, Cu, solder, and combinations thereof, with an optional flux solution. For example, the bump material can be eutectic Sn/Pb, high-lead solder, or lead-free solder. The bump material is bonded to conductive layer 168 using a suitable attachment or bonding process. In one embodiment, the bump material is reflowed by heating the material above its melting point to form balls or bumps 188. In some applications, bumps 188 are reflowed a second time to improve electrical contact to conductive layer 168. Bumps 188 can also be compression bonded or thermocompression bonded to conductive layer 168. Bumps 188 represent one type of interconnect structure that can be formed over conductive layer 168. The interconnect structure can also use bond wires, conductive paste, stud bump, micro bump, or other electrical interconnect.

Bumps 188 are metallurgically and electrically connected to certain portions of substrate 180 and interposer 160 depending on the electrical function of semiconductor die 124 and subsequently mounted semiconductor devices. Interposer 160 is mounted with surface 162 oriented toward semiconductor die 124 and substrate 180. Interposer 160 is oriented such that the narrower surface of interposer 160 faces semiconductor die 124 and substrate 180. Additionally, beveled edge 170 of interposer 160 is oriented toward semiconductor die 124 and substrate 180. In one embodiment, bumps 188 are formed on a strip interposer prior to singulating the strip interposer into individual die-level interposers 160. Interposer 160 with pre-formed bumps 188 is subsequently mounted to substrate 180. In another embodiment, a strip or wafer-form interposer, such as interposer 140, is mounted over substrate 180 at a wafer level and multiple semiconductor die 124 are disposed between substrate 180 and interposer 140 to form semiconductor packages at a wafer-level.

In FIG. 7b, semiconductor package 190 may be placed on carrier 192 and placed between upper mold support 194 and lower mold support 196 of chase mold 198. The upper mold support 194 and lower mold support 196 are brought together to enclose semiconductor package 190 within cavity 200 of chase mold 198. An open space around semiconductor die 124 and between interposer 160 and substrate 180 is filled with encapsulant or molding compound 202. Encapsulant 202 can be a polymer composite material, such as epoxy resin with filler, epoxy acrylate with filler, or polymer with proper filler. Encapsulant 202 is non-conductive, provides physical support, and environmentally protects semiconductor die 124 from external elements and contaminants. In one embodiment, a volume of encapsulant 202 is injected under an elevated temperature and pressure through an inlet of chase mold 198 into cavity 200 over and around semiconductor die 124, and between interposer 160 and substrate 180. In another embodiment, encapsulant 202 in a liquid state is injected into one side of chase mold 198 through a nozzle while a vacuum assist draws pressure from the opposite side to uniformly fill the open space around semiconductor die 124 and between substrate 180 and interposer 160 with the encapsulant 202.

In FIG. 7c, encapsulant 202 is evenly dispersed and uniformly distributed within cavity 200, around semiconductor die 124, and between substrate 180 and interposer 160. Beveled edge 170 of interposer 160 allows for better flow of encapsulant 202 within cavity 200. Encapsulant 202 flows around semiconductor die 124 and around bumps 188. Encapsulant 202 contacts surface 162 and beveled edge 170 of interposer 160, but does not leak or bleed over onto surface 164 of interposer 160. Beveled edge 170 prevents or reduces the overflow of encapsulant 202 onto surface 164 of interposer 160. Therefore, interposer 160 with beveled edge 170 provides a wider mold control range during encapsulation.

After semiconductor package 190 and encapsulant 202 are disposed within chase mold 198, the encapsulant can be partially or completely cured. After encapsulant 202 is partially or completely cured, semiconductor package 210 is removed from chase mold 198. Encapsulant 202 remains between substrate 180 and interposer 140 without flowing onto surface 164 of interposer 160.

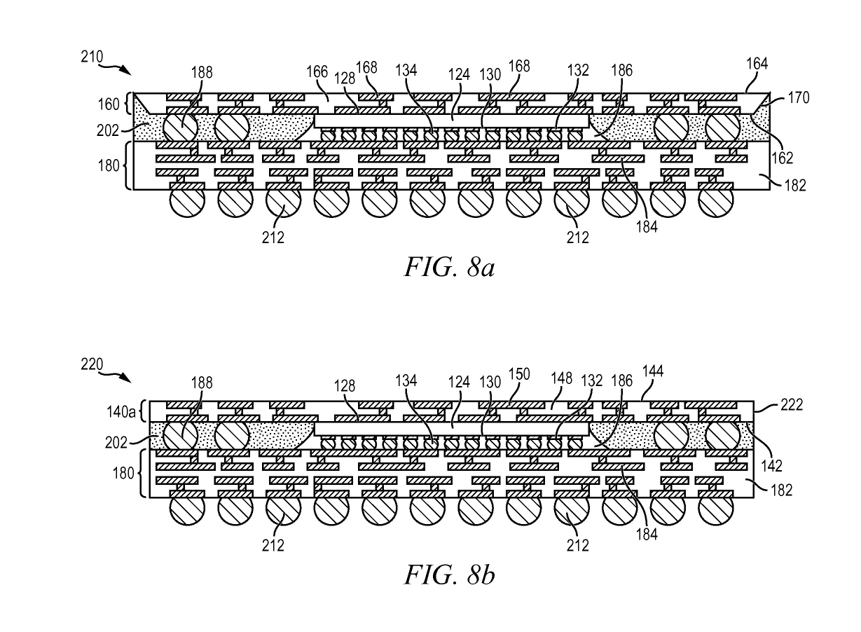

FIGS. 8a-8b show semiconductor packages formed using an interposer having beveled edges. In FIG. 8a, semiconductor package 210 is removed from chase mold 198. An electrically conductive bump material is deposited over conductive layer 184 using an evaporation, electrolytic plating, electroless plating, ball drop, or screen printing process. In one embodiment, the bump material is deposited with a ball drop stencil, i.e., no mask required. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 184 using a suitable attachment or bonding process. In one embodiment, the bump material is reflowed by heating the material above its melting point to form balls or bumps 212. In some applications, bumps 212 are reflowed a second time to improve electrical contact to conductive layer 184. Bumps 212 can also be compression bonded or thermocompression bonded to conductive layer 184. Bumps 212 represent one type of interconnect structure that can be formed over conductive layer 184. The interconnect structure can also use bond wires, conductive paste, stud bump, micro bump, or other electrical interconnect.

Within semiconductor package 210, semiconductor die 124 is mounted over substrate 180 with bumps 134. Semiconductor die 124 is electrically connected to substrate 180 through bumps 134. Underfill 186 is formed between semiconductor die 124 and substrate 180. Interposer 160 including beveled edges 170 is mounted over substrate 180 with bumps 188. Semiconductor die 124 is electrically connected to interposer 160 through bumps 134, conductive layer 184, and bumps 188. Encapsulant 202 fills a gap between interposer 160 and substrate 180. Bumps 212 provide electrical interconnection for semiconductor package 210 for mounting to a substrate or for connection with other system components.

Semiconductor package 210 is configured for stacking additional semiconductor devices over surface 164. Devices mounted over semiconductor package 210 electrically connect to conductive layer 168 on surface 164 of interposer 160. The electrical interface of semiconductor device 210 is not compromised by encapsulant 202, because the flow of encapsulant 202 is more controlled with beveled edges 170 of interposer 160. Encapsulant does not flow onto surface 164, and conductive layer 168 at surface 164 is free of contaminants from encapsulant 202. Semiconductor package 210 including interposer 160 with beveled edge 170 has better electrical performance, because encapsulant 202 is not present on surface 164 of interposer 160. Therefore, semiconductor device 210 with beveled edges 170 is more reliable than a semiconductor device with a conventional top interposer, because surface 164 is free of encapsulant 202.

FIG. 8b shows an alternative semiconductor package formed from a wafer-level beveled interposer. A plurality of semiconductor die 124 is mounted to substrate 180 with bumps 134. Active surface 130 of semiconductor die 124 is oriented towards substrate 180. Underfill 186 is deposited between semiconductor die 124 and substrate 180. Interposer 140, from FIG. 5b, is mounted over wafer-level substrate 180 with bumps 188. Interposer 140 is a strip interposer or wafer-level interposer including beveled edges 152. Surface 142 of interposer 140 is oriented toward semiconductor die 124 and substrate 180 such that the narrower surface of interposer 140 faces semiconductor die 124 and substrate 180. Additionally, beveled edges 152 of interposer 140 are oriented toward semiconductor die 124 and substrate 180. The semiconductor package with interposer 140 is disposed in a chase mold similar to chase mold 198. Similar to the process shown in FIGS. 7a-7c, encapsulant 202 is deposited between interposer 140 and substrate 180 and around semiconductor die 124. Beveled edges 152 of interposer 140 prevents or reduces the overflow of encapsulant 202 onto surface 144 of interposer 140. Therefore, interposer 140 with beveled edge 152 provides a wider mold control range during encapsulation.

After encapsulant 202 is partially or completely cured, the wafer-level semiconductor package is removed from the chase mold. The molded wafer-level semiconductor package including interposer 140 and substrate 180 is singulated through saw streets 154 using a saw blade or laser cutting tool into individual semiconductor packages 220. As a result of the singulation process, interposer 140 with beveled edges 152 is singulated into a plurality of interposers units 140a. In one embodiment, interposer units 140a which are singulated from a central portion of interposer 140 include non-beveled edges 222. In another embodiment, interposer units 140a which are singulated from the peripheral edges of the strip interposer include one or more beveled edges 152.

An electrically conductive bump material is deposited over conductive layer 184 using an evaporation, electrolytic plating, electroless plating, ball drop, or screen printing process. In one embodiment, the bump material is deposited with a ball drop stencil, i.e., no mask required. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 184 using a suitable attachment or bonding process. In one embodiment, the bump material is reflowed by heating the material above its melting point to form balls or bumps 212. In some applications, bumps 212 are reflowed a second time to improve electrical contact to conductive layer 184. Bumps 212 can also be compression bonded or thermocompression bonded to conductive layer 184. Bumps 212 represent one type of interconnect structure that can be formed over conductive layer 184. The interconnect structure can also use bond wires, conductive paste, stud bump, micro bump, or other electrical interconnect.

Within semiconductor package 220, semiconductor die 124 is mounted over substrate 180 with bumps 134. Semiconductor die 124 is electrically connected to substrate 180 through bumps 134. Underfill 186 is formed between semiconductor die 124 and substrate 180. Interposer unit 140a is mounted over substrate 180 with bumps 188. Semiconductor die 124 is electrically connected to interposer unit 140a through bumps 134, conductive layer 184, and bumps 188. Encapsulant 202 fills a gap between interposer unit 140a and substrate 180. Bumps 212 provide electrical interconnection for semiconductor package 220 for mounting to a substrate or for connection with other system components.

Semiconductor package 220 is configured for stacking additional semiconductor devices over surface 144. Devices mounted over semiconductor package 220 electrically connect to conductive layer 150 on surface 144 of interposer unit 140a. The electrical interface of semiconductor device 220 is not compromised by encapsulant 202, because the flow of encapsulant 202 is more controlled with beveled edges 152 of interposer 140. Encapsulant 202 does not flow onto surface 144 of interposer 140, and conductive layer 150 at surface 144 is free of contaminants from encapsulant 202. Interposer 140 with beveled edges 152 results in interposer units 140a in semiconductor package 220 having better electrical performance and reliability than semiconductor packages with conventional interposers, because surface 144 is free of encapsulant 202.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a first substrate;
removing a portion of the first substrate to form a beveled edge; and
depositing an encapsulant over a first surface of the first substrate, wherein the beveled edge reduces encapsulant flow onto a second surface of the first substrate opposite the first surface.

2. The method of claim 1, further including:
disposing a second substrate over the first substrate prior to depositing the encapsulant; and
disposing a semiconductor die over the second substrate.

3. The method of claim 1, further including singulating the first substrate after depositing the encapsulant.

4. The method of claim 1, further including singulating the first substrate before depositing the encapsulant.

5. The method of claim 1, further including forming the beveled edge during singulation of the first substrate.

6. The method of claim 1, further including:
disposing the first substrate in a mold; and
depositing the encapsulant within the mold.

7. A method of making a semiconductor device, comprising:
providing a first substrate;
removing a portion of the first substrate to form a beveled edge; and
depositing an encapsulant over the first substrate.

8. The method of claim 7, further including:
disposing a second substrate over the first substrate prior to depositing the encapsulant; and
disposing a semiconductor die over the second substrate.

9. The method of claim 7, further including singulating the first substrate after depositing the encapsulant.

10. The method of claim 7, further including singulating the first substrate before depositing the encapsulant.

11. The method of claim 7, further including forming the beveled edge during singulation of the first substrate.

12. The method of claim 7, further including:
disposing the first substrate in a mold; and
depositing the encapsulant within the mold.

13. The method of claim 7, wherein the beveled edge reduces encapsulant flow onto a surface of the first substrate.

14. A semiconductor device, comprising:
a first substrate including a beveled edge; and
an encapsulant deposited over the first substrate and over the beveled edge.

15. The semiconductor device of claim 14, further including:
a second substrate disposed over the first substrate; and
the encapsulant deposited between the first and second substrates.

16. The semiconductor device of claim 15, wherein the beveled edge of the first substrate is oriented toward the second substrate.

17. The semiconductor device of claim 14, wherein the encapsulant contacts a first surface of the first substrate while a second surface of the first substrate opposite the first surface remains free from the encapsulant.

18. The semiconductor device of claim 14, further including:
a chase mold including a cavity;
the first substrate disposed within the cavity; and
the encapsulant deposited within the cavity.

19. The semiconductor device of claim 14, wherein the first substrate is a wafer-level interposer or a die-level interposer.

20. A semiconductor device, comprising:
a first substrate including a beveled edge; and
an encapsulant deposited over the first substrate.

21. The semiconductor device of claim 20, wherein the encapsulant contacts a first surface of the first substrate while a second surface of the first substrate opposite the first surface remains free from the encapsulant.

22. The semiconductor device of claim 20, further including a second substrate disposed over the first substrate, wherein the beveled edge of the first substrate is oriented towards the second substrate.

23. The semiconductor device of claim 22, wherein the encapsulant is deposited between the first and second substrates.

24. The semiconductor device of claim 20, further including:
a chase mold including a cavity;
the first substrate disposed within the cavity; and
the encapsulant deposited within the cavity.

25. The semiconductor device of claim 20, further including:
a second substrate disposed over the first substrate; and
a semiconductor die mounted to the second substrate.
